(19) United States
(12) Patent Application Publication
(10) Pub. No.: US 2010/0029093 A1
(43) Pub. Date: Feb. 4, 2010

(54) PLASMA OXIDIZING METHOD, PLASMA PROCESSING APPARATUS, AND STORAGE MEDIUM

(75) Inventors: Toshihiko Shiozawa, Hyogo (JP); Yoshiro Kabe, Hyogo (JP); Takashi Kobayashi, Hyogo (JP); Junichi Kitagawa, Hyogo (JP); Kazuhiro Isa, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, MINATO-KU (JP)

(21) Appl. No.: 12/443,552

(22) PCT Filed: Sep. 27, 2007
(86) PCT No.: PCT/JP07/68756

§ 371 Date: Mar. 30, 2009

(30) Foreign Application Priority Data
Sep. 29, 2006 (JP) 2006-267745
Mar. 30, 2007 (JP) 2007-091702

(51) Int. Cl. H01L 21/316; C23C 16/513

(52) U.S. Cl. 438/772; 118/723 R; 257/E21.283

(57) ABSTRACT

A silicon oxide film forming method includes a step of placing an object to be processed and having a surface having a projecting/recessed pattern and containing silicon in a processing vessel of a plasma processing apparatus, a step of producing a plasma from a processing gas containing oxygen at a proportion of 5 to 20% under a processing pressure of 267 to 400 Pa in the processing vessel, and a step of forming a silicon oxide film by oxidizing silicon in the surface of the object to be processed by the plasma.

### FIELD OF THE INVENTION

The present invention relates to a plasma oxidizing method, and more particularly to a plasma oxidizing method, which is applicable to, e.g., the formation of a silicon oxide film serving as an insulating film in a manufacturing process of various semiconductor devices.

### BACKGROUND OF THE INVENTION

In a manufacturing process of various semiconductor devices, a silicon oxide film, such as SiO₂, is formed as an insulating film, e.g., a gate insulating film of a transistor. In order to form such a silicon oxide film, a thermal oxidation process using an oxidation furnace or a rapid thermal process (RTP) apparatus is used. In a wet oxidation process using an oxidation furnace, which is one of the thermal oxidation processes, a silicon substrate is heated to a temperature exceeding 800° C. and exposed to an oxidizing atmosphere of water vapor (H₂O) by using a water vapor generator (WVG), which generates vapor (H₂O) through the combustion of oxygen and hydrogen, thereby oxidizing a surface of the silicon substrate to form a silicon oxide film.

The thermal oxidation process is considered as a process of forming a silicon oxide film of a good quality. However, the thermal oxidation process requires a high temperature exceeding 800° C., and thus causes problems, such as the increase of a thermal budget, the distortion of a silicon substrate due to thermal stress, or the like.

On the other hand, there is proposed an oxide film forming method as a technique capable of avoiding the increase of the thermal budget or the distortion of the silicon substrate in the thermal oxidation process (see, e.g., WO2001/69673). In this method, an oxidation process is performed on the surface of an electronic device mainly containing silicon by using a microwave-excited plasma, which is formed at a pressure of 133.3 Pa in a chamber using a processing gas including Ar gas and oxygen gas, the proportion of the flow rate of oxygen in the processing gas being approximately 1%. Accordingly, it is possible to form a silicon oxide film having a good quality and easily controlled film thickness.

In case that the plasma process is carried out under the condition that the process pressure is approximately 133.3 Pa and the proportion of the flow rate of O₂ in the processing gas is 1% (for convenience of description, referred to as a low-pressure and low-oxygen concentration condition), for example, when a pattern, such as lines and spaces formed on an object to be processed, has dense and sparse portions, there is a difference of forming speeds of the silicon oxide film between dense portions and sparse portions, and it is difficult to form the silicon oxide film with a uniform thickness. If the thickness of the silicon oxide film varies according to the portions of the film, the reliability of a semiconductor device using the silicon oxide film as an insulating film may be lowered.

In order to solve this problem, the plasma oxidation process is carried out under the condition that the process pressure is approximately 667 Pa and the proportion of the flow rate of O₂ in the processing gas is approximately 25% (for convenience of description, referred to as a high-pressure and high-oxygen concentration condition). In this case, however, when a silicon oxide film is formed on a pattern having prominences and depressions, an oxidation rate at a dense portion is lowered, and corners of the upper ends of the prominences are not sufficiently rounded. Thus, leakage current due to electric field concentration on these portions or cracks due to stress of the silicon oxide film may be generated.

That is, in case that a silicon oxide film is formed by the plasma oxidation process, it is required to round corners of the upper ends of prominences of the pattern and also to form the silicon oxide film having a uniform film thickness regardless of the density of the pattern. Further, it is required to form the silicon oxide film with an extremely high throughput.

### SUMMARY OF THE INVENTION

It is an object of the present invention to provide a plasma oxidizing method capable of forming a silicon oxide film, which does not generate a film thickness difference due to the density of a pattern, allows corners of upper ends of prominences of the pattern to be rounded, and obtains a uniform film thickness.

It is another object of the present invention to provide a plasma oxidizing method capable of forming a silicon oxide film with an extremely high throughput.

In accordance with a first aspect of the present invention, there is provided a plasma oxidizing method comprising: placing an object to be processed, having a surface containing silicon and an uneven pattern with prominences and depressions, in a processing chamber of a plasma processing apparatus; forming a plasma in the processing chamber under the condition that a proportion of oxygen in a processing gas ranges from 5 to 20% and a process pressure ranges from 267 Pa to 400 Pa; and forming a silicon oxide film by oxidizing the silicon of the surface of the object by using the plasma.

In the first aspect, preferably, the plasma is a microwave-excited plasma formed by exciting the processing gas by using a microwave introduced into the processing chamber by a planar antenna having plural slots.

In accordance with a second aspect of the present invention, there is provided a plasma oxidizing method comprising: placing an object to be processed, having a surface containing silicon, in a processing chamber of a plasma processing apparatus; forming a plasma of a processing gas including rare gas and oxygen in the processing chamber by radiating a microwave from a planar antenna having plural slots into the processing chamber; and forming a silicon oxide film by oxidizing the silicon of the surface of the object by using the plasma, wherein the plasma is formed under the condition the processing gas including oxygen of 5 to 20% is supplied into the processing chamber at a flow rate of 0.128 mL/min or more per unit volume (1 mL) of a plasma processing space, in which a plasma process is effectively carried out in the processing chamber, and a process pressure ranges from 267 Pa to 400 Pa, and the silicon oxide film is formed by oxidizing the silicon of the surface of the object by using the plasma.

In the second aspect, preferably, the processing gas including oxygen of 5 to 20% is supplied into the processing chamber at a flow rate of 2,000 mL/min or more, when the volume of the plasma processing space, in which the plasma process is effectively carried out in the processing chamber, ranges from 15 to 16 L.

In the first and second aspects, preferably, the processing gas further includes a hydrogen gas, and the surface of the object includes an uneven pattern having prominences and depressions.

Preferably, the uneven pattern formed on the surface of the object includes sparse and dense portions having sparse and dense prominences and depressions.

Preferably, the silicon oxide film is formed such that a ratio (t_{c}/tₛ) of a film thickness t_{c} of the silicon oxide film formed at corners of upper ends of prominences of the uneven pattern to a film thickness tₛ of the silicon oxide film formed at side surfaces of the prominences ranges from 0.95 to 1.5.

Preferably, the silicon oxide film is formed such that a ratio of a film thickness of the silicon oxide film formed at bottoms of the depressions of the uneven pattern at dense portions to a film thickness of the silicon oxide film formed at bottoms of the depressions of the uneven pattern at sparse portions is 85% or more.

Preferably, the proportion of oxygen in the processing gas ranges from 10 to 18%, and the process pressure ranges from 300 Pa to 350 Pa.

Preferably, the processing gas includes hydrogen in a proportion of 0.1 to 10%.

Preferably, a process temperature ranges from 200 to 800° C.

In accordance with a third aspect of the present invention, there is provided a plasma processing apparatus comprising: a processing chamber which accommodates an object to be processed, having a surface containing silicon and an uneven pattern with prominences and depressions; a processing gas supply unit which supplies a processing gas including rare gas and oxygen into the processing chamber; a gas exhaust unit which evacuates the processing chamber to form a vacuum in the processing chamber; a plasma generating unit which generates a plasma of the processing gas in the processing chamber; and a control unit which controls the units to form the plasma in the processing chamber in which the object is placed under the condition that a proportion of oxygen in the processing gas ranges from 5 to 20% and a process pressure ranges from 267 Pa to 400 Pa, and to form a silicon oxide film by oxidizing the silicon in the surface of the object by using the plasma.

In accordance with a fourth aspect of the present invention, there is provided a storage medium storing a program which runs on a computer and, when executed, controls a plasma processing apparatus to perform a plasma oxidizing method including: placing an object to be processed, having a surface containing silicon and an uneven pattern with prominences and depressions, in a processing chamber of the plasma processing apparatus; forming the plasma in the processing chamber in which the object is placed under the condition that a proportion of oxygen in the processing gas ranges from 5 to 20% and a process pressure ranges from 267 Pa to 400 Pa; and forming a silicon oxide film by oxidizing the silicon in the surface of the object by using the plasma.

In accordance with the aspects of the present invention, silicon of the surface of an object to be processed, having a pattern with prominences and depressions, is oxidized by using the plasma formed under the condition that a proportion of oxygen in the processing gas ranges from 5 to 20% and a process pressure ranges from 267 Pa to 400 Pa, thereby forming a silicon oxide film. Accordingly, it is possible to suppress a film thickness difference due to the density and to round corners of the upper ends of the prominences of the pattern of the silicon surface. Thus, a silicon oxide film having a uniform film thickness can be formed on the silicon surface having the pattern with the prominences and the depressions. Therefore, the silicon oxide film obtained by the method of the present invention provides excellent electrical characteristics to a semiconductor device using the silicon oxide film as an insulating film and also improves the reliability of the semiconductor device.

However, the inventors of the present invention have found that a throughput tends to be lowered in case that the silicon oxide film is formed by using the plasma obtained by irradiating a microwave from a planar antenna having plural slots into the processing chamber using the above condition.

Thus, the inventors have investigated in order to solve this problem, and found that an oxidation rate is increased and the throughput is improved by setting the flow rate of the processing gas to 2,000 mL/min or more in case that the proportion of oxygen in the processing gas ranges from 5 to 20%, the process pressure ranges from 267 Pa to 400 Pa, and the volume of a plasma processing space, in which the plasma process is effectively carried out in the processing chamber, ranges from 15 to 16 L. Further, when the flow rate of the processing gas per unit volume of the plasma processing space, in which the plasma process is effectively carried out in the processing chamber, is a predetermined value or more, the oxidation rate increasing effect can be achieved regardless of the volume of the processing chamber. Specifically, when the flow rate of the processing gas is 0.128 mL/min or more per unit volume (1 mL) of the plasma processing space, the oxidation rate is increased and the throughput is improved.

### BRIEF DESCRIPTION OF THE DRAWINGS

FIG. 1 schematically shows a cross sectional view of one example of a plasma processing apparatus suitable for the execution of a method in accordance with the present invention.

FIG. 2 illustrates the structure of a planar antenna plate.

FIG. 3 is a flow chart illustrating an oxidation process of trenches using the plasma processing apparatus of FIG. 1.

FIG. 4 is illustrates results of the silicon oxide films formed by varying a process time under a high-pressure and high-oxygen concentration condition and a medium-pressure and medium-oxygen concentration condition.

FIG. 5 is a diagram for explaining a plasma processing space, in which a plasma process is effectively carried out in a chamber.

FIG. 6 illustrates the variation of a film thickness when the total flow rate of the processing gas is varied under the medium-pressure and medium-oxygen concentration condition.

FIG. 7 illustrates Arrhenius plots, in which a reciprocal of a temperature is represented by the horizontal axis and a diffusion rate constant in oxidation is represented by the vertical axis, under a low-pressure and low-oxygen concentration condition, a high-pressure and high-oxygen concentration condition, and a medium-pressure and medium-oxygen concentration condition.

FIG. 8 illustrates relationships among a process time, a film thickness, and a variation of the film thickness when a preheating time is set to 35 seconds, as conventional, and 10 seconds, in formation of a silicon oxide film under the medium-pressure and medium-oxygen concentration condition.

FIG. 9 schematically shows a cross sectional view of a wafer illustrating an application example of the method of the present invention to device isolation through an STI process.

FIG. 10 is a longitudinal cross sectional view schematically showing the surface of a wafer having a pattern.

FIG. 11 is a graph illustrating a relationship between film thickness ratios of a silicon oxide film and a process pressure.

FIG. 12 is a graph illustrating a relationship between film thickness ratios of a silicon oxide film and an oxygen proportion in the processing gas.

FIG. 13 is a graph illustrating a relationship between a film thickness ratio of a silicon oxide film due to a pattern density and a process pressure.

FIG. 14 is a graph illustrating a relationship between a film thickness ratio of a silicon oxide film due to a pattern density and an oxygen proportion in the processing gas.

FIG. 15 is a graph illustrating a relationship between a film thickness ratio of a silicon oxide film due to plane directions and a process pressure.

FIG. 16 is a graph illustrating a relationship between a film thickness ratio of a silicon oxide film due to plane directions and an oxygen proportion in the processing gas.

FIG. 17A is a timing chart illustrating the conventional sequence.

FIG. 17B is a timing chart illustrating the sequence obtained by increasing the flow rate of the processing gas and shortening an oxidation process time.

FIG. 17C is a timing chart illustrating the sequence obtained by decreasing a preheating time in addition to the increase of the flow rate of the processing gas and the shortening of the oxidation process time.

### DETAILED DESCRIPTION OF THE EMBODIMENTS

Hereinafter, embodiments of the present invention will be described in detail with reference to the accompanying drawings.

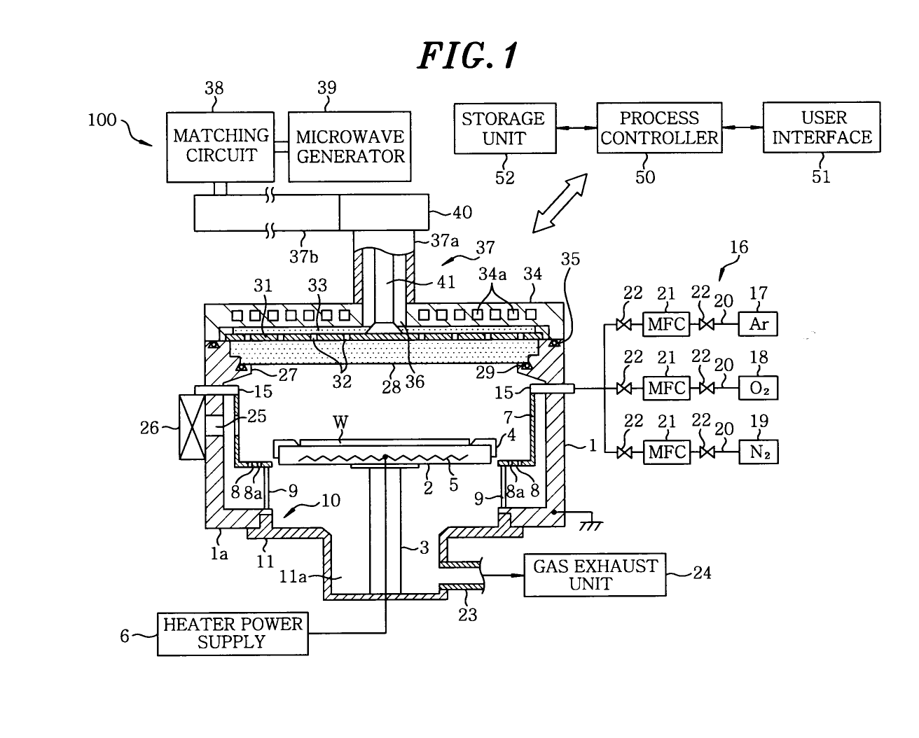

FIG. 1 is a cross sectional view schematically illustrating an example of a plasma processing apparatus for performing a silicon oxide film forming method in accordance with the present invention. The plasma processing apparatus is configured as a radial line slot antenna (RLSA) microwave plasma processing apparatus which introduces a microwave from a planar antenna with many slots, particularly a RLSA, into a processing chamber to generate a microwave plasma having a high density and a low electron temperature. The plasma processing apparatus may be suitably used to form insulating films of various semiconductor devices, e.g., a gate insulating film of a transistor.

The plasma processing apparatus 100 includes an approximately cylindrical chamber 1, which is airtightly sealed and grounded. A circular opening 10 is formed at an approximately central portion of a bottom wall 1a of the chamber 1. A gas exhaust chamber 11, which is connected to the opening 10 and is protruded downwardly, is installed on the bottom wall 1a.

A susceptor 2 made of ceramic such as AlN is installed in the chamber 1 to horizontally support a substrate to be processed, i.e., a semiconductor wafer W. The susceptor 2 is supported by a cylindrical support member 3 which is made of ceramic such as AlN and is extended upwardly from a central bottom portion of the gas exhaust chamber 11. A guide ring 4 for guiding the wafer W is installed at an outer peripheral portion of the susceptor 2. Further, a resistance heater 5 is embedded in the susceptor 2. The resistance heater 5 is supplied with power from a heater power supply 6 to heat the susceptor 2, thereby heating the wafer W. In this case, a process temperature can be controlled within a range, for example, from a room temperature to 800° C. Further, a cylindrical liner 7 made of quartz is installed inside the chamber 1. A baffle plate 8, which is made of quartz and has a plurality of gas exhaust holes 8a, is installed in a ring shape at the outside of the susceptor 2 to uniformly evacuate the chamber 1. The baffle plate 8 is supported by several pillars 9.

Wafer supporting pins (not shown) are provided in the susceptor 2 to be protruded from the surface of the susceptor 2 and retracted into the susceptor 2, thereby supporting and moving the wafer W up and down.

A gas inlet member 15 having a ring shape is provided at a sidewall of the chamber 1, and gas inlet holes are uniformly formed through the gas inlet member 15. A gas supply system 16 is connected to the gas inlet member 15. The gas inlet member 15 may have a showerhead shape. For example, the gas supply system 16 includes an Ar gas supply source 17, an O₂ gas supply source 18 and a H₂ gas supply source 19. Ar, O₂ and H₂ gases reach the gas inlet member 15 via respective gas lines 20 and are uniformly introduced into the chamber 1 through the gas inlet holes of the gas inlet member 15. Each of the gas lines 20 is provided with a mass flow controller 21 and valves 22 located at the upstream and downstream sides of the mass flow controller 21. The Ar gas may be replaced by another rare gas, e.g., Kr gas, He gas, Ne gas, Xe gas or the like, and the rare gas may be omitted, as will be described later.

A gas exhaust pipe 23 is connected to the side surface of the gas exhaust chamber 11, and a gas exhaust unit 24 including a high speed vacuum pump is connected to the gas exhaust pipe 23. As the gas exhaust unit 24 is operated, the gas in the chamber 1 uniformly moves to a space 11a of the gas exhaust chamber 11 and is discharged through the gas exhaust pipe 23. Accordingly, the inner pressure of the chamber 1 may be rapidly lowered down to a predetermined vacuum level of, e.g., 0.133 Pa.

At the sidewall of the chamber 1, there are provided a loading/unloading port 25 through which the wafer W is delivered between the chamber 1 and a transfer chamber (not shown) adjacent to the plasma processing apparatus 100, and a gate valve 26 for opening and closing the loading/unloading port 25.

An opening is formed at an upper portion of the chamber 1, and a support part 27 having a ring shape is installed along the circumference of the opening. A microwave transmitting plate 28, which is made of a dielectric, for example, ceramic such as quartz or Al₂O₃ and transmits a microwave, is airtightly installed at the support part 27 through a seal member 29. Therefore, the inside of the chamber 1 can be maintained in a hermetically sealed state.

A planar antenna plate 31 having a circular plate shape is installed above the microwave transmitting plate 28 to face the susceptor 2. The planar antenna plate 31 is suspended on the upper end of the sidewall of the chamber 1. When the wafer W has a size of, e.g., 8 inches, the planar antenna plate 31 is configured as a circular plate, which has a diameter of 300 to 400 mm and a thickness of 1 to several mm (e.g., 1 mm) and is made of a conductive material. Specifically, the planar antenna plate 31 is formed of a silver or gold plated steel plate or an aluminum plate, and a plurality of microwave radiation holes (slots) 32 are formed in a specific pattern through the planar antenna plate 31. The planar antenna plate 31 may be formed of a nickel plate or a stainless steel plate. As shown in FIG. 2, the microwave radiation holes 32 have pairs of long slots, wherein each pair of the microwave radiation holes 32 are generally arranged in a “T” shape. The pairs of the microwave radiation holes 32 are arranged in plural concentric circles. The length and arrangement interval of the microwave radiation holes 32 depend on the wavelength (λg) of the microwave. For example, the microwave radiation holes 32 may be arranged at intervals of λg/4, λg/2 or λg. In FIG. 2, an interval between adjacent microwave radiation holes 32 on different concentric circles is represented by Δr. Also, the microwave radiation holes 32 may have a circular shape, a circular arc shape or the like. No particular limitation is imposed on the arrangement of the microwave radiation holes 32. For example, the microwave radiation holes 32 may be arranged in a spiral or radial pattern in addition to the concentric circular pattern.

A wave retardation member 33, which is made of a dielectric material having a larger dielectric constant than that of a vacuum, for example, quartz, is installed on the upper surface of the planar antenna plate 31. The wave retardation member 33 may be made of resin, such as polytetrafluorethylene or polyimide. Since the microwave has a longer wavelength in a vacuum, the wave retardation member 33 functions to shorten the wavelength of the microwave to control the plasma. Further, the planar antenna member 31 may be in contact with or separated from the transmitting plate 28 and the wave retardation member 33.

A shield cover 34, serving as a waveguide, which is made of metal such as aluminum, stainless steel or copper, is installed on the upper surface of the chamber 1 to cover the planar antenna plate 31 and the wave retardation member 33. The upper surface of the chamber 1 and the shield cover 34 are sealed with a seal member 35. Cooling water paths 34a are formed in the shield cover 34, and cooling water flows through the cooling water paths 34a to cool the shield cover 34, the wave retardation member 33, the planar antenna plate 31 and the microwave transmitting plate 28. Further, the shield cover 34 is grounded.

An opening 36 is formed at the center of an upper wall of the shield cover 34, and a waveguide 37 is connected to the opening 36. A microwave generator 39 is connected to the end of the waveguide 37 via a matching circuit 38. Accordingly, a microwave generated from the microwave generator 39 and having a frequency of, e.g., 2.45 GHz is propagated to the planar antenna plate 31 via the waveguide 37. Further, the microwave may have a frequency of 8.35 GHz, 1.98 GHz, or the like.

The waveguide 37 includes a coaxial waveguide 37a having a circular cross sectional shape, which is extended upwardly from the opening 36 of the shield cover 34, and a rectangular waveguide 37b, which is connected to the upper end of the coaxial waveguide 37a via a mode converter 40 and is extended in the horizontal direction. The mode converter 40 provided between the coaxial waveguide 37a and the rectangular waveguide 37b functions to convert a microwave propagating in a TE mode through the rectangular waveguide 37b into a TEM mode microwave. An internal conductor 41 is provided at the center of the coaxial waveguide 37a, and a lower end of the internal conductor 41 is fixed to the center of the planar antenna plate 31. Accordingly, the microwave is uniformly and efficiently propagated to the planar antenna plate 31 via the internal conductor 41 of the coaxial waveguide 37a.

Each component of the plasma processing apparatus 100 is connected to and controlled by a process controller 50 having a CPU. A user interface 51, including a keyboard for inputting commands or a display for displaying an operation status of the plasma processing apparatus 100, is connected to the process controller 50 to allow a process manager to manage the plasma processing apparatus 100.

Further, the process controller 50 is connected to a storage unit 52 which stores recipes including control programs for implementing various processes in the plasma processing apparatus 100 under control of the process controller 50, or a program for performing a process in each component of the plasma processing apparatus 100 under process conditions. Further, the recipes can be stored in a storage medium of the storage unit 52. The storage medium may be a hard disk, a semiconductor memory, or a portable storage medium, such as a CD-ROM, a DVD, or a flash memory. Further, the recipes may properly be transmitted from another apparatus via, e.g., a dedicated line.

If necessary, as a certain recipe is retrieved from the storage unit 52 in accordance with an instruction inputted through the user interface 51 and transmitted to the process controller 50, a desired process is performed in the plasma processing apparatus 100 under control of the process controller 50.

The plasma processing apparatus 100 having the above configuration can provide a film having good quality by performing a damage-free plasma process even at a low temperature of 800° C. or less, and preferably 500° C. or less while achieving both excellent plasma uniformity and process uniformity.

The plasma processing apparatus 100 may be applied to a case in which a silicon oxide film is formed as a gate insulating film of a transistor as described above, and a case in which an oxide film is formed in a trench through an oxidation process (liner oxidation) in a shallow trench isolation (STI) process for device isolation in a manufacturing process of a semiconductor device.

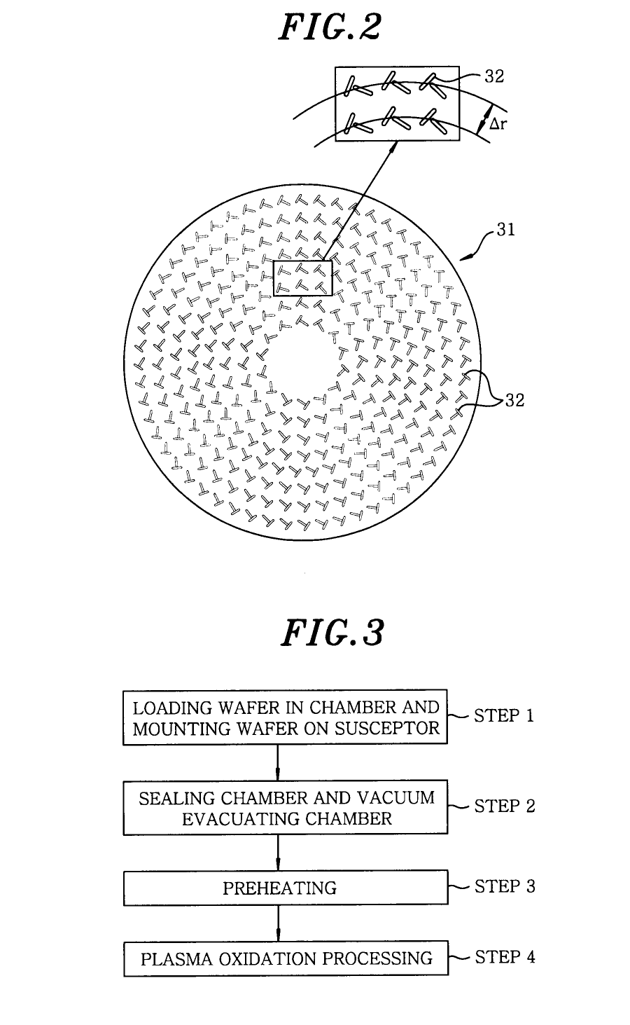

Now, referring to the flow chart of FIG. 3, an oxidation process of trenches (depressions) using the plasma processing apparatus 100 will be described. First, the gate valve 26 is opened, and a wafer W with trenches is loaded from the loading port 25 into the chamber 1, and is mounted on the susceptor 2 (step 1).

Thereafter, the chamber 1 is sealed and is evacuated to allow the inside of the chamber 1 to reach a high vacuum (step 2). Then, Ar gas and O₂ gas from the Ar gas supply source 17 and the O₂ gas supply source 18 of the gas supply system 16, or Ar gas, O₂ gas and H₂ gas from the H₂ gas supply source 19 are supplied to the inside of the chamber 1 at specific flow rates via the gas inlet member 15, and simultaneously, the susceptor 2 starts to be heated to a predetermined temperature by the heater 5 embedded in the susceptor 2 (preheating; step 3). After the preheating is carried out for a specific period of time, the processing gas is converted into a plasma by introducing the microwave into the chamber 1 under the condition that the inside of the chamber 1 is maintained at a predetermined pressure and a predetermined temperature, and then a plasma oxidation process is carried out (step 4).

During the plasma oxidation process, the processing gas including Ar gas and O₂ gas, or the processing gas including Ar gas, O₂ gas and H₂ gas is introduced into the chamber 1 continuously from the preheating, and under the above state, the microwave from the microwave generator 39 passes through the matching circuit 38, the waveguide 37, the planar antenna plate 31, and the microwave transmitting plate 28, and is radiated to a space above the wafer W in the chamber 1. Then, the processing gas in the chamber 1 is converted into a plasma by the microwave, and the plasma oxidation process of the wafer W is carried out by the plasma.

Specifically, the microwave from the microwave generator 39 reaches the waveguide 37 via the matching circuit 38, and the microwave in the waveguide 37 sequentially passes through the rectangular waveguide 37b, the mode converter 40, and the coaxial waveguide 37a, and is supplied to the planar antenna plate 31. Then, the microwave is radiated from the planar antenna plate 31 to the space above the wafer W in the chamber 1 via the microwave transmitting plate 28. The microwave is propagated in the TE mode within the rectangular waveguide 37b, and the TE mode microwave is converted into a TEM mode microwave in the mode converter 40. The TEM mode microwave is propagated within the coaxial waveguide 37a toward the planar antenna plate 31. Preferably, the microwave generator 39 is set at a power density of 0.41 to 4.19 W/cm² and at a power level of 0.5 to 5 kW.

An electromagnetic field is formed in the chamber 1 by the microwave radiated from the planar antenna plate 31 into the chamber 1 via the microwave transmitting plate 28, and Ar gas, O₂ gas and the like are converted into a plasma. The silicon surface exposed in the depressions of the wafer W is oxidized by the plasma. This microwave plasma is a high-density plasma having a density of approximately 1×10¹⁰ to 5×10¹²/cm³ or more, which is obtained by radiating the microwave through the plural microwave radiation holes 32 of the planar antenna plate 31, and has an electron temperature of 0.5 to 2 eV and plasma density uniformity of ±5% or less. Therefore, the method of the present invention is advantageous in that a thin and uniform oxide film can be formed by carrying out the oxidation process at a low temperature for a short period of time, and the oxide film suffers little damage due to ions in the plasma by using the plasma having a low electron temperature, thereby forming a silicon oxide film having a good quality.

As the plasma oxidation process is carried out under the condition that a process pressure ranges from 267 Pa to 400 Pa and a proportion of oxygen in the processing gas ranges from 5 to 20%, it is possible to round corners of the upper ends of the trenches and to form a silicon oxide film having a uniform film thickness regardless of the density of a pattern formed on the surface an object to be processed, simultaneously, as will be described later. Therefore, a semiconductor device using the silicon oxide film obtained by this method as an insulating film has good electrical characteristics.

In case of the above low-pressure and low-oxygen concentration condition, ion components become dominant as active species in the plasma, an electric field produced by the plasma is concentrated on corners, at which the oxide film is difficult to be grown, and the active species are attracted into the corners to accelerate the radical oxidation. Accordingly, an oxidation rate difference is generated by the density difference of the pattern, and thus it is difficult to form a uniform oxide film.

On the other hand, in case of the high-pressure and high-oxygen concentration condition, as described above, the density difference is small, but radicals of active species mainly contribute to the oxidation. Accordingly, ion assistance is insufficient to sufficiently round the corners of the prominences of the pattern.

However, in case of the medium-pressure and medium-oxygen concentration condition of the present invention, it is possible to obtain the effect of enough ion-assist to favorably round the corners as in a case of the low-pressure and low-oxygen concentration condition, and to render uniform the film thickness of the oxide film regardless of the density difference of the pattern as in a case of the high-pressure and high-oxygen concentration condition.

In the plasma process, the proportion of oxygen in the processing gas ranges preferably from 5 to 20%, as described above, and more preferably from 10 to 18%. By adjusting the proportion of oxygen in the processing gas within this range, the amount of oxygen ions or oxygen radicals in plasma can be controlled, and, even when there is a pattern having, e.g., prominences and depressions on the silicon surface, the amount of oxygen ions or oxygen radicals reaching the bottoms of the depressions can be increased, and thus it is possible to form a silicon oxide film having a uniform thickness.

The gas flow rates of the processing gas under the medium-pressure and medium-oxygen concentration condition may be selected within a range of Ar gas of 50 to 5,000 mL/min and a range of O₂ gas of 5 to 500 mL/min, such that the proportion of oxygen to a total flow rate of the processing gas meets the above condition.

Further, in addition to Ar gas and O₂ gas from the Ar gas supply source 17 and the O₂ gas supply source 18, H₂ gas from the H₂ gas supply source 19 may be introduced into the chamber 1 at a specific proportion, as described above. An oxidation rate in the plasma oxidation process can be improved by supplying H₂ gas. When H₂ gas is supplied, OH radicals are generated to contribute to the improvement of the oxidation rate. In this case, the proportion of H₂ gas in the total amount of the processing gas is preferably 0.01 to 10%, more preferably 0.1 to 5%, and desirably 0.1 to 2%. Specifically, it is preferable that the flow rate of Ar gas is 50 to 5,000 mL/min, the flow rate of O₂ gas is 10 to 500 mL/min, and the flow rate of H₂ gas is 1 to 110 mL/min. Further, a H₂/O₂ ratio ranges preferably from 0.1 to 0.5.

A process pressure in the chamber 1 ranges preferably from 267 to 400 Pa (2 to 3 Torr), as described above, and more preferably from 300 to 350 Pa (2.2 to 2.7 Torr).

Further, a process temperature is selected from the range of 200 to 800° C., and ranges preferably from 400 to 500° C.

According to test results of inventors of the present invention, in this embodiment that the proportion of O₂ gas in the processing gas ranges from 5 to 20% and the pressure in the chamber ranges from 267 to 400 Pa (hereinafter, referred to as the medium-pressure and medium-oxygen concentration condition), it is proved that a film thickness formed per unit time is small compared to film thicknesses formed under the low-pressure and low-oxygen concentration condition and the high-pressure and high-oxygen concentration condition. That is, it takes a longer time to obtain a certain film thickness, thereby reducing a throughput.

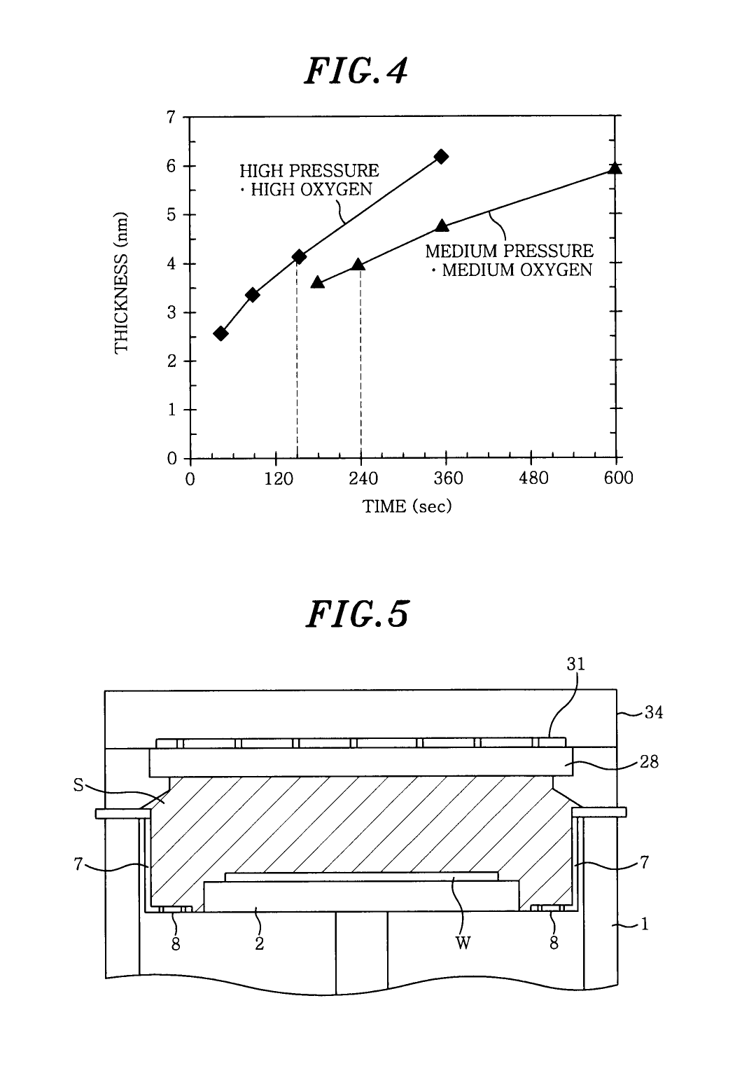

The above effect is shown in FIG. 4. FIG. 4 illustrates results of the silicon oxide films formed on a wafer of 300 mm by varying a processing time under the high-pressure and high-oxygen concentration condition that the proportion of O₂ gas in the total processing gas is 23% and the pressure in the chamber is 665 Pa (5 Torr), and the medium-pressure and medium-oxygen concentration condition that the proportion of O₂ gas in the total processing gas is 12.7% and the pressure in the chamber is 333 Pa (2.5 Torr) within the above ranges. Further, in both cases, the processing gas included O₂ gas, Ar gas, and H₂ gas. The flow rate of O₂ gas was set to 37 mL/min(sccm), the flow rate of Ar gas was set to 120 mL/min(sccm), the flow rate of H₂ gas was set to 3 mL/min(sccm), and the total flow rate was set to 160 mL/min(sccm) under the high-pressure and high-oxygen concentration condition. The flow rate of O₂ gas was set to 102 mL/min(sccm), the flow rate of Ar gas was set to 680 mL/min(sccm), the flow rate of H₂ gas was set to 18 mL/min(sccm), and the total flow rate was set to 800 mL/min(sccm) under the medium-pressure and medium-oxygen concentration condition. Further, the output of the microwave was set to 4,000 W, and the process temperature (susceptor temperature) was set to 465° C. Further, the volume of a plasma processing space S, which is represented by oblique lines in FIG. 5, is approximately 15.6 L. The plasma processing space S corresponds to a region from the baffle plate 8 to the lower surface of the microwave transmitting plate 28 within the liner 7 of the chamber 1, in which a plasma process is effectively carried out in the chamber 1.

As shown in FIG. 4, a film forming speed under the medium-pressure and medium-oxygen concentration condition of this embodiment is slower than that under the high-pressure and high-oxygen concentration condition. For example, when a target film thickness is 4 nm, the film forming speed under the high-pressure and high-oxygen concentration condition is 150 seconds, whereas the film forming speed under the condition of this embodiment is 240 seconds, which is approximately 60% longer than that under the high-pressure and high-oxygen concentration condition. This tendency is the same as in a case using Ar gas and O₂ gas as the processing gas.

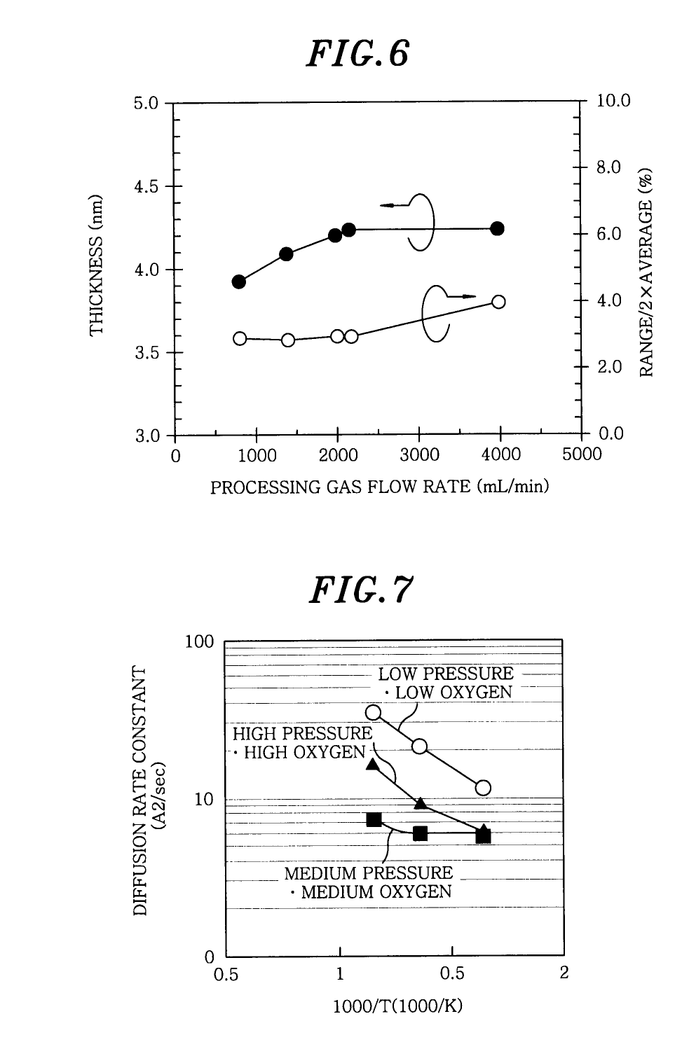

Therefore, a variation of the film thickness was inspected by varying the total flow rate of the processing gas to 800, 1,400, 2,000, and 4,000 mL/min(sccm) under the medium-pressure and medium-oxygen concentration condition of this embodiment. FIG. 6 illustrates the obtained results. In this case, the processing gas included O₂ gas, Ar gas, and H₂ gas, and the proportion of O₂ gas in the processing gas was set to 15%. Further, a Ar:O₂:H₂ ratio was set to 680:102:18 when the total amount of the processing gas is 800 mL/min and to 1,870:280.5:49.5 when the total amount of the processing gas is 2,200 mL/min. Further, the pressure was set to 333 Pa, the output of the microwave was set to 4,000 W, and the process temperature (susceptor temperature) was set to 465° C. As shown in FIG. 6, the film thickness increases as the total flow rate of the processing gas increases when the total flow rate ranges from 800 to 2,000 mL/min(sccm), and the film thickness is saturated when the total flow rate is 2,000 mL/min(sccm) or more. That is, it can be known that a high throughput (productivity) is obtained when the total flow rate of the processing gas is 2,000 mL/min(sccm) or more. Therefore, the total flow rate of the processing gas is preferably 2,000 mL/min(sccm) or more in order to improve productivity by shortening a film forming time. That is, it was confirmed that it is effective to increase the total flow rate of the processing gas by 2.5 or more times than the conventional flow rate. Further, even though there may be some errors in the volume of the chamber, the volume of the plasma processing space S, in which the plasma process is effectively carried out on a wafer of 300 mm in the chamber, ranges from 15 to 16 L. In this case, when the total flow rate of the processing gas is 2,000 mL/min(sccm) or more, it is possible to obtain an effect of improving the oxidation rate.

Further, the productivity improvement effect obtained by shortening the film forming time depends on the total flow rate of the processing gas per unit volume of the plasma processing space, in which the plasma process is effectively carried out in the chamber. If the total flow rate is equal to or larger than a predetermined value, the effect can be achieved regardless of the volume of the chamber. In the chamber shown in FIG. 5, the total flow rate is 2,000 mL/min(sccm) or more for the volume (15.6 L) of the plasma processing space, in which the plasma process is effectively carried out. Accordingly, it is preferable that the total flow rate of the processing gas is 0.128 mL/min or more per 1 mL of the plasma processing space, in which the plasma process is effectively carried out in the chamber.

The oxidation rate is varied according to the variation of the temperature under the conventional low-pressure and low-oxygen concentration condition and the high-pressure and high-oxygen concentration condition for reducing a film thickness difference due to the density of the pattern. Accordingly, the preheating of the step 3 is set to be performed for a sufficient time period of 35 seconds in order to stabilize the temperature of the substrate and the inside of the chamber, thereby stabilizing the oxidation rate.

However, according to investigation results of the inventors, it was proved that the temperature dependency of the oxidation rate under the medium-pressure and medium-oxygen concentration condition of this embodiment is lower than those under the low-pressure and low-oxygen concentration condition and the high-pressure and high-oxygen concentration condition.

The results are shown in FIG. 7. FIG. 7 illustrates Arrhenius plots, in which a reciprocal of a temperature is represented by the horizontal axis and a diffusion rate constant is represented by the vertical axis, under the low-pressure and low-oxygen concentration condition, the high-pressure and high-oxygen concentration condition, and the medium-pressure and medium-oxygen concentration condition. The low-pressure and low-oxygen concentration condition, the high-pressure and high-oxygen concentration condition, and the medium-pressure and medium-oxygen concentration condition are as follows.

<High-Pressure and High-Oxygen Concentration Condition>

O₂ gas: 370 mL/min(sccm)

Ar gas: 1,200 mL/min(sccm)

H₂ gas: 30 mL/min(sccm)

Pressure: 665 Pa (5 Torr)

<Medium-Pressure and Medium-Oxygen Concentration Condition>

O₂ gas: 280.5 mL/min(sccm)

Ar gas: 1,870 mL/min(sccm)

H₂ gas: 49.5 mL/min(sccm)

Pressure: 333 Pa (2.5 Torr)

<Low-Pressure and Low-Oxygen Concentration Condition>

O₂ gas: 20 mL/min(sccm)

Ar gas: 2,000 mL/min(sccm)

H₂ gas: 10 mL/min(sccm)

Pressure: 133 Pa (1 Torr)

As shown in FIG. 7, the diffusion rate constants in the oxidation process are greatly varied according to the variation of the temperature under the low-pressure and low-oxygen concentration condition and the high-pressure and high-oxygen concentration condition, whereas the diffusion rate constant is rarely varied according to the variation of the temperature under the medium-pressure and medium-oxygen concentration condition. This fact represents that the medium-pressure and medium-oxygen concentration condition of this embodiment does not require temperature stability to obtain film thickness stability as much as the low-pressure and low-oxygen concentration condition and the high-pressure and high-oxygen concentration condition. Thus, it proves that the preheating time can be shortened under the medium-pressure and medium-oxygen concentration condition of this embodiment.

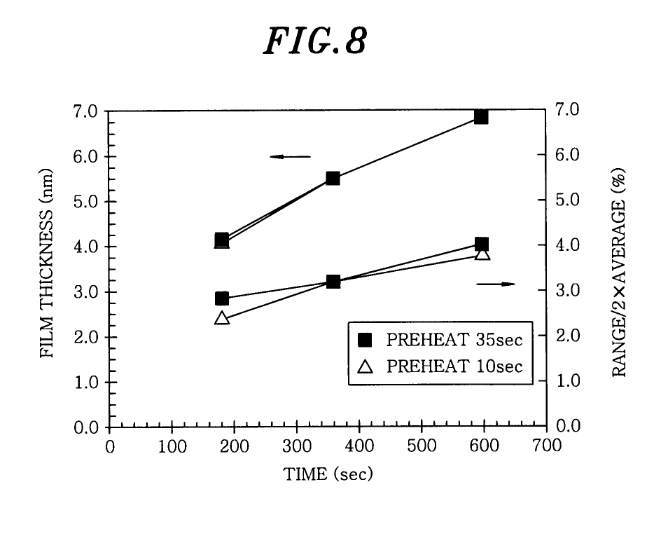

Based on the above results, an experiment was conducted to obtain relationships among a process time, a film thickness, and a variation of the film thickness. In this experiment, silicon oxide films were formed under the medium-pressure and medium-oxygen concentration condition of this embodiment by setting a preheating time to 35 seconds as in a conventional case, and 10 seconds. The obtained results are shown in FIG. 8. As shown in FIG. 8, under the medium-pressure and medium-oxygen concentration condition of this embodiment, even in a case of the preheating time of about 10 seconds, it was possible to obtain a silicon oxide film formation rate and the film thickness stability similar to those in a case of the preheating time of 35 seconds, thereby greatly shortening the preheating time. It is preferable that the preheating time ranges from 5 to 25 seconds from the viewpoint that the process time can be sharply shortened while maintaining the film thickness stability. Further, it is more preferable that the preheating time ranges from 5 to 15 seconds from the viewpoint of the throughput.

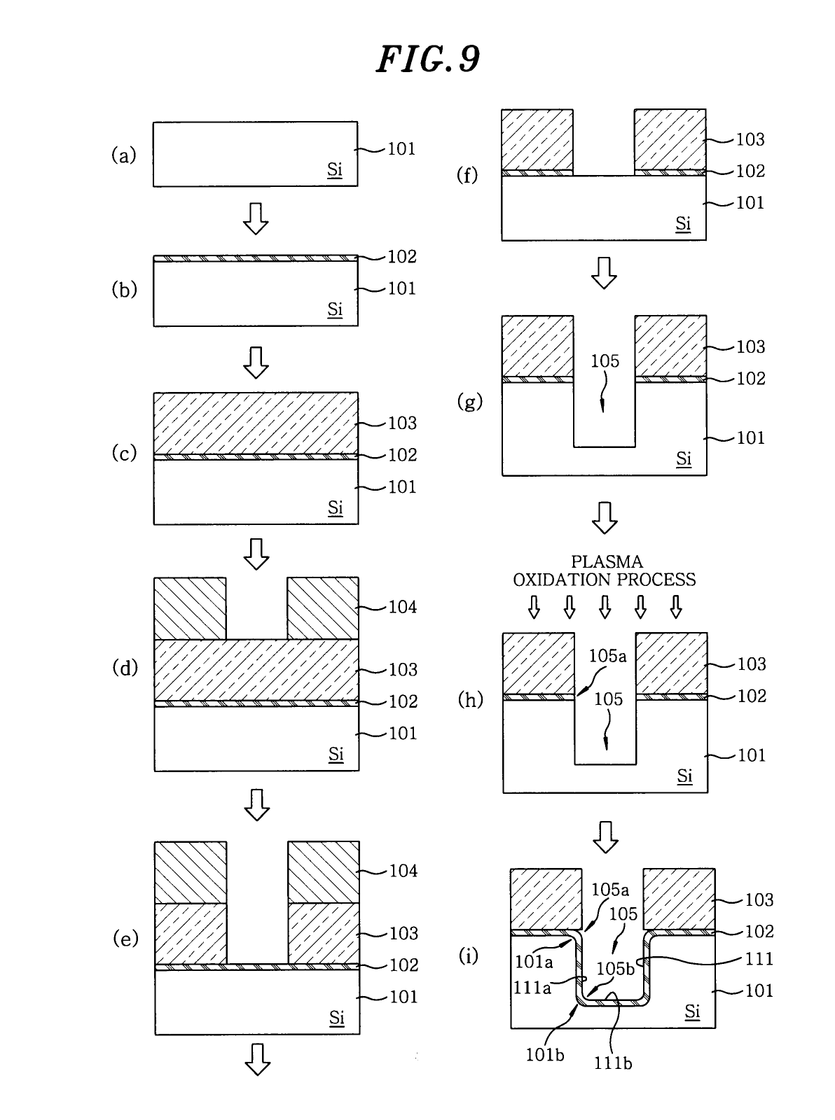

Next, referring to FIG. 9, an application example of the plasma oxidation method of the present invention to the formation of an oxide film in trenches in the STI process will be described. FIG. 9 illustrates a process including the formation of the trenches and the formation of the silicon oxide film carried out after the formation of the trenches in the STI process.

First, as shown in (a) and (b) of FIG. 9, a silicon oxide film 102 made of SiO₂ is formed on a silicon substrate 101 by using, e.g., the thermal oxidation method. Thereafter, as shown in (c) of FIG. 6, a silicon nitride film 103 made of Si₃N₄ is formed on the silicon oxide film 102 by using, e.g., chemical vapor deposition (CVD). Thereafter, as shown in (d) of FIG. 6, a photoresist is coated on the silicon nitride film 103, and is patterned by a photolithography to form a resist layer 104.

Thereafter, as shown in (e) of FIG. 6, the silicon oxide film 102 and the silicon nitride film 103 are selectively etched through an etching mask of the resist layer 104 by using, e.g., a fluorocarbon-based etching gas to thereby expose the silicon substrate 101 corresponding to the pattern of the resist layer 104. That is, the silicon nitride film 103 forms a mask pattern for forming trenches. Further, (f) of FIG. 6 shows the state of the silicon substrate 101, in which ashing is carried out by, e.g., an oxygen containing plasma obtained by using a processing gas containing oxygen to remove the resist layer 104.

As shown in (g) of FIG. 6, trenches 105 are formed by selectively etching (dry etching) the silicon substrate 101 through a mask of the silicon nitride film 103 and the silicon oxide film 102. The etching of the silicon substrate 101 may be carried out by using halogen or a halogen compound, such as Cl₂, HBr, SF₆ and CF₄, or an etching gas including O₂ or the like.

Next, (h) of FIG. 9 shows the formation of a silicon oxide film on the exposed surfaces of the trenches 105 formed in the silicon substrate 101 after etching in the STI process. In this case, the plasma oxidation process is carried out under the medium-pressure and medium-oxygen concentration condition that the proportion of oxygen in the processing gas ranges from 5 to 20% and the process pressure ranges from 267 Pa to 400 Pa. By carrying out the plasma oxidation process under the above condition, as shown in (i) of FIG. 9, it is possible to round the silicon substrate 101 at shoulder parts 105a of the trenches 105 and form the silicon oxide film on the exposed surfaces of the trenches 105. The generation of leakage current is suppressed by rounding the silicon substrate 101 at the shoulder parts 105a of the trenches 105, compared to a case that these parts are formed at an acute angle.

Further, even when the pattern with prominences and depressions has dense and sparse portions, it is possible to form a uniform silicon oxide film on the surfaces of trenches (recesses) without generating a film thickness difference between the sparse portions and the dense portions.

A (100) plane is generally used as a crystal plane direction of the silicon substrate 101. When the trenches 105 are formed by etching the substrate 101, a (111) plane or (110) plane is exposed from the sidewalls in the trenches 105, and the (100) plane is exposed from the bottoms of the trenches 105. When an oxidation process is performed on the trenches 105, oxidation rates are different according to plane directions, and there is a difference between oxide film thicknesses on the respective surfaces, thereby causing plane direction dependency. However, it is possible to form a silicon oxide film 111a and 111b having a uniform thickness on the inner surfaces (sidewalls and bottoms) of the trenches 105 without depending on the plane directions of the silicon substrate 101 by carrying out the plasma oxidation process under the oxidation process condition of the present invention. This is the peculiar effect of the plasma oxidation process performed under the condition that the proportion of oxygen in the processing gas ranges from 5 to 20% and the process pressure ranges from 267 Pa to 400 Pa. In this case, the partial pressure of oxygen ranges from 13.3 to 80 Pa. When the proportion of oxygen in the processing gas is in the more preferable range of 10 to 18%, the partial pressure of oxygen ranges from 26.6 to 72 Pa.

Further, after the silicon oxide film 111 is formed by the silicon oxide film forming method of the present invention, in accordance with the procedure of forming device isolation regions through the STI process, an insulating film made of SiO₂ is buried in the trenches 105, e.g., by chemical vapor deposition (CVD). Then, the polarization of the silicon substrate 101 is carried out by chemical mechanical polishing (CMP) using the silicon nitride film 103 as a stopper layer. After the planarization, the silicon nitride film 103 and an upper portion of the buried insulating film are removed to thereby form a device isolation structure.

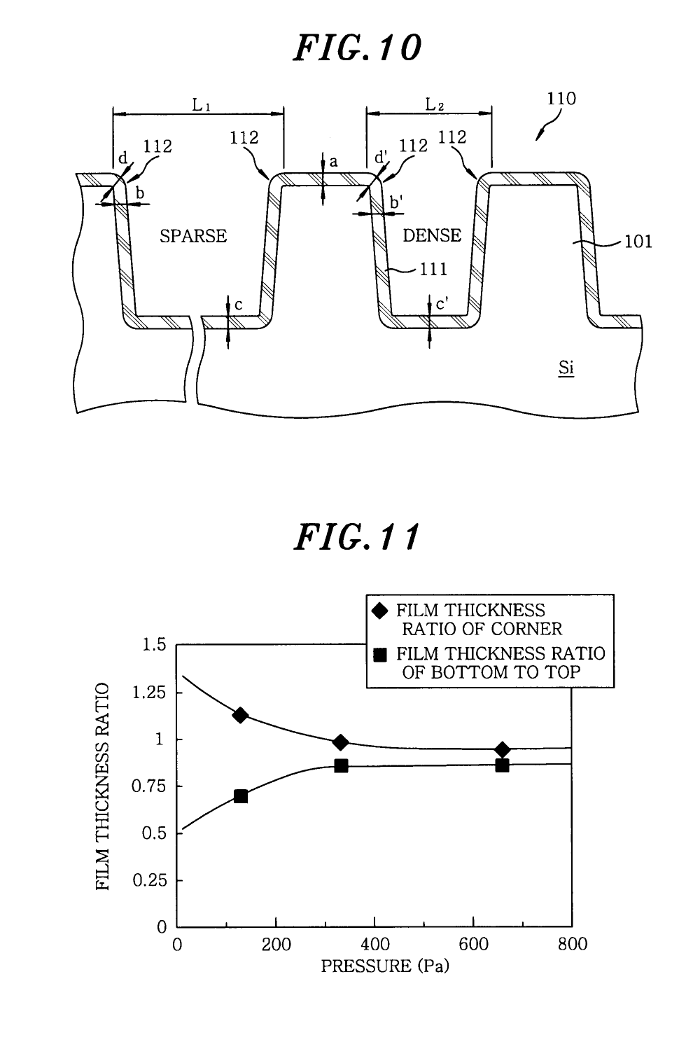

Next, an example of the application of the silicon oxide film forming method of the present invention to the formation of an oxide film on the surface of a silicon substrate having a pattern with prominences and depressions of lines and spaces with dense and sparse portions will be described. FIG. 10 schematically illustrates the cross sectional structure of essential parts of a wafer W after a silicon oxide film 111 is formed on the surface of a silicon substrate 101 having a pattern 110.

The plasma oxidation process was carried out by using the plasma processing apparatus 100 of FIG. 1 while varying a process pressure and an oxygen proportion under the following conditions A to C, thereby forming silicon oxide films on the surfaces of the silicon substrates, each having a pattern with prominences and depressions. Then, the top film thickness a of prominences of the patterns 110; the side film thickness b, the bottom film thicknesses c, and the corner film thickness d of shoulder parts 112 at sparse portions of the pattern 110; and the side film thickness b′, the bottom film thickness c′, and the corner film thickness d′ of shoulder parts 112 at dense portions of the patterns 110 were measured. Further, in each of the patterns 110 with the prominences and depressions, a ratio (L₁/L₂) of an opening width L₁ of a depression at a sparse portion of the pattern 110 to an opening width L₂ of a depression at a dense portion of the pattern 110 was 10 or more. Further, a ratio (aspect ratio) of a depth to an opening width of a depression of the pattern 110 was 1 or more at a sparse portion, and was 2 at a dense portion.

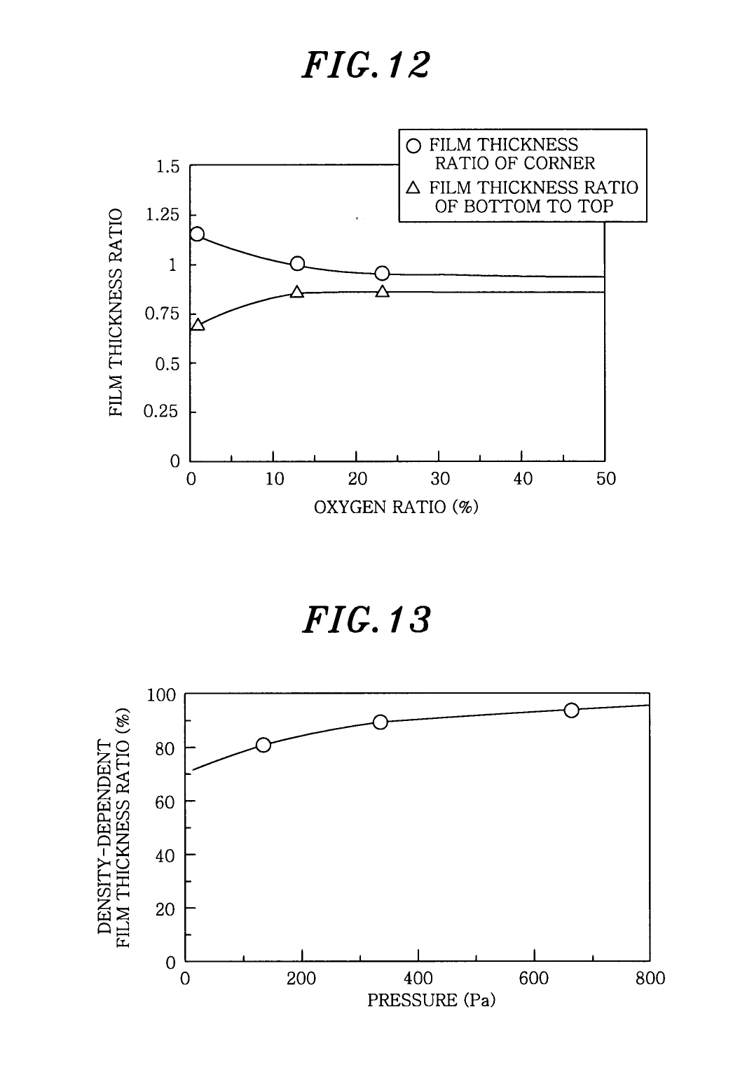

In the formed silicon oxide films, corner film thickness ratios (film thickness d′/film thickness b′) of prominences of the patterns 110, bottom-to-top film thickness ratios (film thickness c′/film thickness a) of the patterns 110, and film thickness ratios ((film thickness c′/film thickness c)×100) due to the density of the patterns 110 were measured. Table 1 and FIGS. 11 to 14 show results of the above measurement. FIG. 11 is a graph illustrating a relationship between film thickness ratios of a silicon oxide film and a process pressure. FIG. 12 is a graph illustrating a relationship between film thickness ratios of a silicon oxide film and an oxygen proportion in processing gas. FIG. 13 is a graph illustrating a relationship between a film thickness ratio of a silicon oxide film due to a pattern density and a process pressure. FIG. 14 is a graph illustrating a relationship between a film thickness ratio of a silicon oxide film due to a pattern density and an oxygen proportion in processing gas.

The corner film thickness ratio (film thickness d′/film thickness b′) represents a rounded degree of the shoulder parts 112 of each of the patterns 110. For example, when the corner film thickness ratio is 0.8 or more, the corners of the silicon substrate 101 at the shoulder parts 112 are rounded. The corner film thickness ratio ranges preferably from 0.8 to 1.5, more preferably from 0.95 to 1.5, and even more preferably from 0.95 to 1.0. On the other hand, when the corner film thickness ratio is less than 0.8, the corners of the silicon substrate 101 are not sufficiently rounded and are formed at an acute angle. When the corners of the silicon substrate 101 are formed at an acute angle, an electric field is concentrated on the corners after the formation of a device, thereby increasing leakage current.

Further, the bottom-to-top film thickness ratio (film thickness c′/film thickness a) represents coverage on the silicon substrate having prominences and depressions, and the closer to 1 the bottom-to-top film thickness ratio is, the better the coverage on the silicon substrate is.

Further, the film thickness ratio due to the density ((film thickness c′/film thickness c)×100) is an index of a film thickness difference between sparse and dense portions of the pattern 110, and is preferably 85% or more.

<Condition A; Comparison Example 1>

Ar flow rate: 500 mL/min(sccm)

O₂ flow rate: 5 mL/min(sccm)

H₂ flow rate: 0 mL/min(sccm)

O₂ gas proportion: approximately 1%

Process pressure: 133.3 Pa (1 Torr)

Microwave power density: 2.30 W/cm²

Process temperature: 400° C.

Process time: 360 seconds

<Condition B; Present Invention>

Ar flow rate: 340 mL/min(sccm)

O₂ flow rate: 51 mL/min(sccm)

H₂ flow rate: 9 mL/min(sccm)

O₂ gas proportion: approximately 13%

Process pressure: 333.3 Pa (2.5 Torr)

Microwave power density: 2.30 W/cm²

Process temperature: 400° C.

Process time: 585 seconds

<Condition C; Comparison Example 2>

Ar flow rate: 120 mL/min(sccm)

O₂ flow rate: 37 mL/min(sccm)

H₂ flow rate: 3 mL/min(sccm)

O₂ gas proportion: approximately 23%

Process pressure: 666.5 Pa (5 Torr)

Microwave power density: 2.30 W/cm²

Process temperature: 400° C.

Process time: 444 seconds

TABLE 1

| | Condition A | Condition B | Condition C |
|---|---|---|---|
| | (Comparison | (Present | (Comparison |
| | Example 1) | Invention) | Example 2) |
| Corner film thickness | 1.14 | 0.99 | 0.94 |
| ratio (film thickness | | | |
| d′/film thickness b′) | | | |
| Bottom-to-top Film | 0.70 | 0.86 | 0.86 |
| thickness ratio | | | |
| (film thickness | | | |
| c′/film thickness a) | | | |
| Film thickness ratio | 81.5 | 89.4 | 93.8 |
| due to density | | | |
| (film thickness | | | |
| c′/film thickness c) × | | | |
| 100) [%] | | | |

From Table 1 and FIGS. 11 and 12, it was confirmed that the corner film thickness ratio of the pattern of the silicon oxide film formed under the condition A (the Comparison example 1)>the corner film thickness ratio under the condition B (the present invention)>the corner film thickness ratio under the condition C (the Comparison example 2). That is, the corner film thickness ratio, i.e., 0.99, under the condition B (the present invention) was good, although it was lower than the corner film thickness ratio, i.e., 1.14, under the condition A (the Comparison example 1) of the relatively low-pressure and low-oxygen concentration condition. Accordingly, the silicon substrate at the shoulder parts 112 of the silicon oxide film formed under the condition B (the present invention) was sufficiently rounded. However, the corner film thickness ratio, i.e., 0.94, under the condition C (the Comparison example 2) of the relatively high-pressure and high-oxygen concentration condition did not reach the value of 0.95. Accordingly, the silicon substrate at the shoulder parts 112 of the silicon oxide film formed under the condition C (the Comparison example 2) was not sufficiently rounded. Further, it was confirmed that the bottom-to-top film thickness ratio of the pattern of the silicon oxide film formed under the condition B (the present invention)>the bottom-to-top film thickness ratio under the condition C (the Comparison example 2)>the bottom-to-top film thickness ratio under the condition A (the Comparison example 1). That is, the coverage under the condition B (the present invention) and the condition C (the Comparison example 2) was excellent, whereas the coverage under the condition A (the Comparison example 1) was poor.

Further, from Table 1 and FIGS. 13 and 14, it was confirmed that the film thickness ratio due to the density of the pattern of the silicon oxide film formed under the condition C (the Comparison example 2)>the film thickness ratio due to the density under the condition B (the present invention)>the film thickness ratio due to the density of the pattern under the condition A (the Comparison example 1). That is, the film thickness ratio, i.e., 89.4%, due to the density of the pattern under the condition B (the present invention) was excellent, although it was lower than the film thickness ratio, i.e., 93.8%, due to the density of the pattern under the condition C (the Comparison example 2) of the relatively high-pressure and high-oxygen concentration condition. On the other hand, the film thickness ratio, i.e., 81.5%, due to the density of the pattern under the condition A (the Comparison example 1) of the relatively low-pressure and low-oxygen concentration condition was greatly lower than those under other conditions.

As for the reason, the density of oxygen radicals in the plasma is high and the radicals easily enter into the depressions of the pattern 110 having prominences and depressions under the condition B (the present invention) and the condition C (the Comparison example 2) of the relatively high-pressure and high-oxygen concentration condition, compared to the condition A (the Comparison example 1) of the relatively low-pressure and low-oxygen concentration condition. Thus, under the conditions B and C, there is a small film thickness difference due to the density of the pattern, and the satisfied results can be obtained.

As described above, the silicon oxide films formed under the condition A (the Comparison example 1) of the relatively low-pressure and low-oxygen concentration condition and the condition C (the Comparison example 2) of the relatively high-pressure and high-oxygen concentration condition did not satisfy all characteristics since the corner film thickness or the film thickness due to the density was poor. However, the silicon oxide film formed under the condition B (the present invention) satisfied all characteristics.

Further, from the above test results, it is confirmed that the process pressure is set to 400 Pa or less and the oxygen proportion in the processing gas is 20% or less in order that the corner film thickness ratio is 0.8 or more, and more preferably 0.95 or more. On the other hand, it is confirmed that the process pressure is set to 267 Pa or more and the oxygen proportion in the processing gas is 5% or more in order that the film thickness ratio due to the density of the pattern is 85% or more. Therefore, it is confirmed that the process pressure ranges preferably from 267 Pa to 400 Pa, and the proportion of oxygen in the processing gas is ranges preferably from 5% to 20% and more preferably from 10% to 18% in the plasma oxidation process.

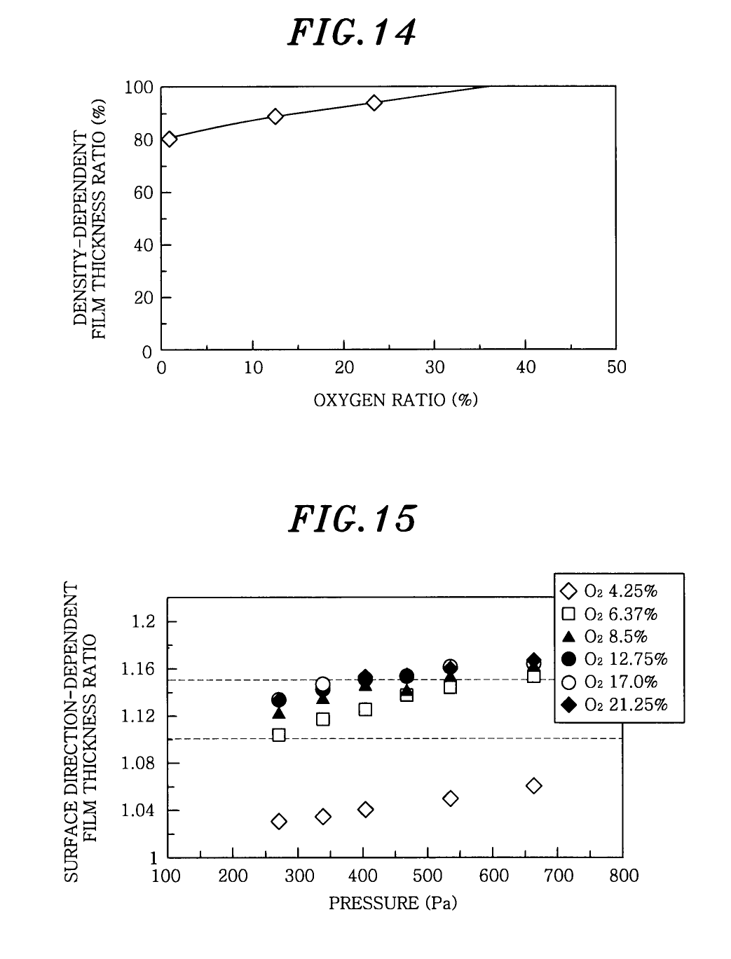

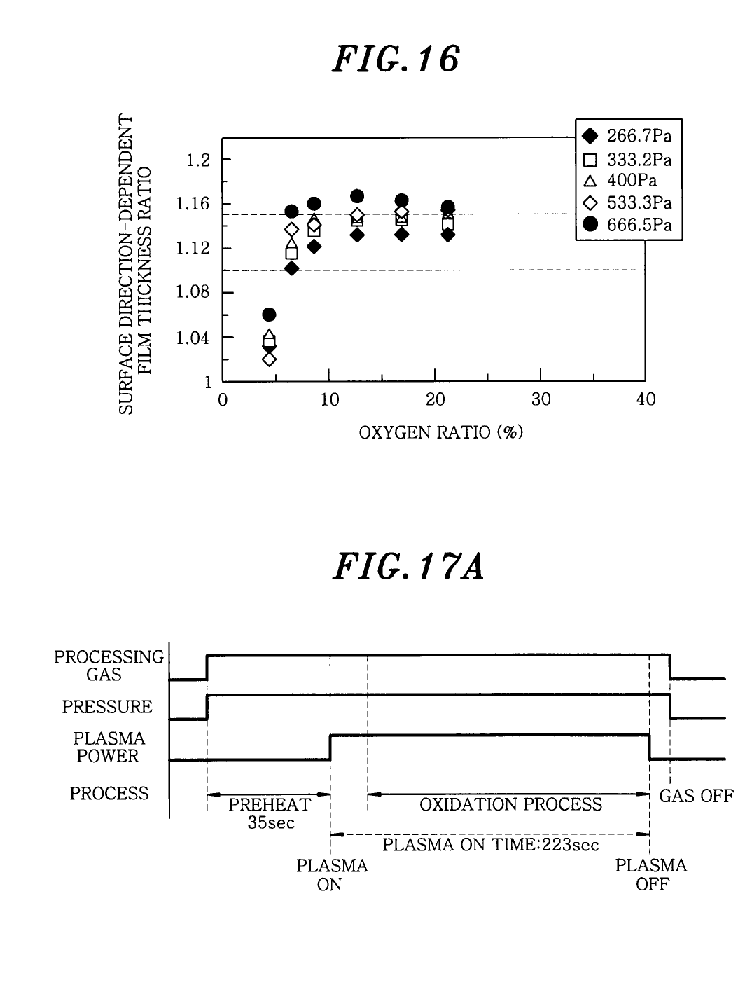

Thereafter, in the plasma processing apparatus 100, the plasma oxidation process was carried out on silicon of the (100) and (110) crystal planes while using Ar, O₂, and H₂ as a processing gas at the total flow rate of 800 mL/min(sccm), and a film thickness ratio (the film thickness of the (110) plane/the film thickness of the (100) plane) due to plane directions was measured. A proportion of oxygen in the processing gas was varied to 4.25%, 6.37%, 8.5%, 12.75%, 17.0%, and 21.25%, and the flow rates of Ar and H₂ were controlled such that the total flow rate of the processing gas meets the above value. Further, a process pressure was varied to 266.7 Pa, 333.2 Pa, 400 Pa, 533.3 Pa, and 666.5 Pa. Further, a H₂/O₂ flow rate ratio was fixed to 0.176. Further, a microwave power was set to 2,750 W (power density: 2.30 W/cm²), a process temperature was set to 400° C., and a process time was set to 360 seconds. FIGS. 15 and 16 show the obtained results.

In case that a silicon oxide film is formed, it is important to make uniform the film thickness of the (110) plane at sides of a pattern having prominences and depressions and the film thickness of the (100) plane at bottoms of the pattern, as much as possible. This film thickness ratio (the film thickness of the (110) plane/the film thickness of the (100) plane) due to plane directions is preferably 1.15 or less, and more preferably 1.1 to 1.15.

From FIGS. 15 and 16, it is confirmed that the film thickness ratio (the film thickness of the (110) plane/the film thickness of the (100) plane) due to plane directions is 1.15 or less, e.g., 1.1 to 1.15, when the plasma oxidation process is carried out under the condition that the process pressure ranges from 267 Pa to 400 Pa and the proportion of oxygen in the processing gas ranges from 5 to 20%.

Although the film thickness ratio (the film thickness of the (110) plane/the film thickness of the (100) plane) due to plane directions is preferably 1.0 or more, the film thickness ratio due to the density is not satisfied when the film thickness ratio due to plane directions is 1.0. In order to make the film thickness ratio due to the density to be 85% or more, the film thickness ratio due to plane directions is required to be 1.1 or more. Further, when the film thickness ratio due to plane directions is 1.1 or more, the corner film thickness ratio can be maintained within a favorable range.

From the above test results, as a silicon oxide film is formed by using the plasma processing apparatus 100 under the condition that the process pressure ranges from 267 Pa to 400 Pa and the proportion of oxygen in the processing gas ranges from 5 to 20%, it is possible to round the shoulder parts 112 of the pattern 110 having prominences and depressions and also possible to reduce the film thickness difference due to the density of the pattern 110 and the film thickness difference due to plane directions. These effects are sufficiently obtained when the ratio (L₁/L₂) of an opening width L₁ of a depression at a sparse portion of the pattern 110 to an opening width L₂ of a depression at a dense portion of the pattern 110 is 1 or more, e.g., 2 to 10, as shown in FIG. 10. Further, the above effects are obtained when the ratio (aspect ratio) of a depth to an opening width of a depression of the pattern 110 is 1 or less, preferably 0.02 to 1, at a sparse portion and the aspect ratio is 2 to 10, preferably 5 to 10, at a dense portion. Further, a uniform silicon oxide film can be formed even when the pattern 110 having prominences and depressions is extremely fine.

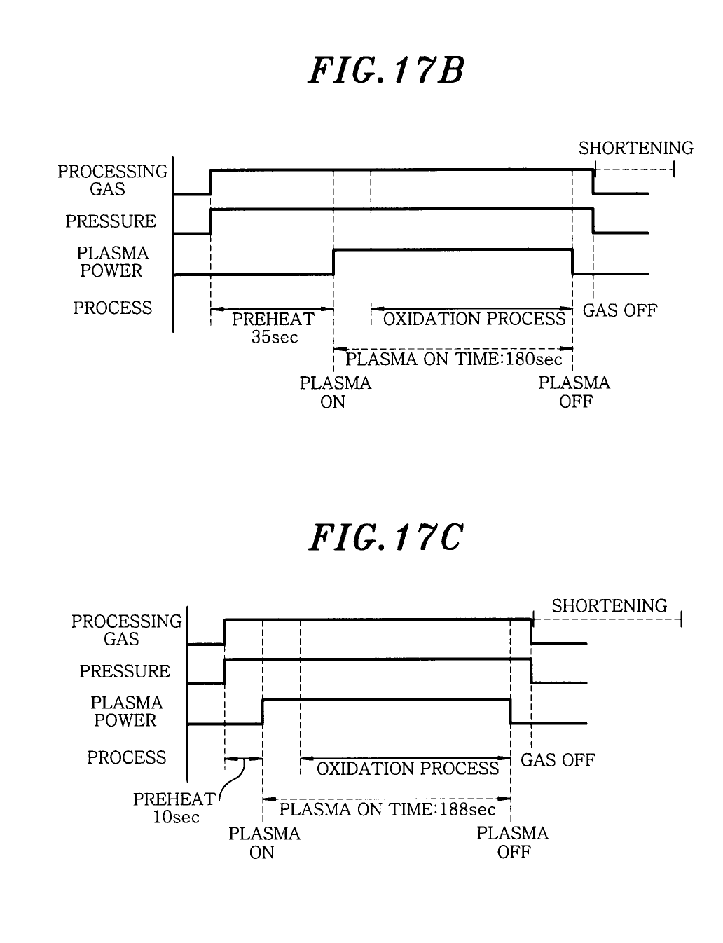

Next, results of a test for shortening a process time will be described. In this case, the total flow rate of the processing gas was set to 800 mL/min(sccm) and 2,200 mL/min(sccm), and the preheating time was set to 35 seconds and 10 seconds when the total flow rate of the processing gas was set to 2,200 mL/min(sccm) under the medium-pressure and medium-oxygen concentration condition of this embodiment that the pressure in the chamber was 333 Pa (2.5 Torr), the proportion of O₂ gas in the total flow rate of the processing gas was 12.75%, the proportion of H₂ gas in the total flow rate of the processing gas was 2.25%, the process temperature was 465° C., and the microwave power was 4,000 W (power density: 3.35 W/cm²). Further, for comparison, under the high-pressure and high-oxygen concentration condition, a silicon oxide film was formed by varying the preheating time. Under the condition that the pressure in the chamber was 665 Pa (5 Torr), the proportion of O₂ gas in the total flow rate of the processing gas was 23%, the proportion of H₂ gas in the total flow rate of the processing gas was 2.25%, the process temperature was 465° C., and the microwave power was 4,000 W (power density: 3.35 W/cm²), a silicon oxide film of 4.2 nm was formed at the preheating time of 35 seconds, the plasma process time of 145 seconds, and the total time of 180 seconds, as shown in Table 2 (case A in Table 2). On the other hand, in order to obtain a silicon oxide film of 4.2 nm under the medium-pressure and medium-oxygen concentration condition that the total flow rate of the processing gas was 800 mL/min(sccm) (case B in Table 2), it took 35 seconds for the preheating time and 223 seconds for the plasma process time, and thus the total time of 258 seconds is longer than that under the high-pressure and high-oxygen concentration condition by 78 seconds. FIG. 17A illustrates the sequence in this case. However, the plasma process time for obtaining the silicon oxide film of 4.2 nm was shortened up to 180 seconds (case C in Table 2) by raising the total flow rate of the processing gas to 2,200 mL/min(sccm), the plasma process time in this case was shorter than the plasma process time when the total flow rate of the processing gas was 800 mL/min(sccm) by 43 seconds, and a time difference with the plasma process time under the high-pressure and high-oxygen concentration condition was shortened to 35 seconds. FIG. 17B illustrates the sequence in this case. Further, although the preheating time was shortened to 10 seconds when the total flow rate of the processing gas was 2,200 mL/min(sccm) (case D in Table 2), the plasma process time was not increased so much, and the film thickness difference was substantially equal to that when the preheating time was 35 seconds. Since the plasma process time was 188 seconds and the preheating time was 10 seconds in this case, as shown in Table 2, the total time of 198 seconds was longer than that in the case A under the high-pressure and high-oxygen concentration condition by 18 seconds, and thus the case D was considered to be approximately equal to that in the case A. FIG. 17C illustrates the sequence in this case.

TABLE 2

| | | | | Plasma | Preheating | \textcircled{1} + | Time |
|---|---|---|---|---|---|---|---|
| | | Total flow | Power | ON (sec) | time (sec) | \textcircled{2} | difference |
| | Condition | rate (mL/min) | (W) | \textcircled{1} | \textcircled{2} | (sec) | with A (sec) |
| A | High pressure | 160 | 4,000 | 145 | 35 | 180 | — |
| | and high oxygen | | | | | | |
| B | Medium pressure | 800 | 4,000 | 223 | 35 | 258 | 78 |
| C | and medium oxygen | 2,200 | | 180 | 35 | 215 | 35 |
| D | | | | 188 | 10 | 198 | 18 |

The present invention may be variously modified without being limited to the above embodiment. For example, although the above embodiment exemplifies an RLSA type plasma processing apparatus, other plasma processing apparatuses such as a remote plasma type plasma processing apparatus, an ICP plasma type plasma processing apparatus, an ECR plasma type plasma processing apparatus, a surface reflected wave plasma type plasma processing apparatus, a magnetron plasma type plasma processing apparatus or the like may be used.

Further, although the above embodiment exemplifies the formation of an oxide film in trenches in the STI process requiring the formation of an oxide film having a high quality on a pattern, having prominences and depressions, of a single-crystal silicon substrate, as shown in FIGS. 9 and 10, the present invention may be applied to the formation of an oxide film having a high quality on the surfaces of other patterns having prominences and depressions, such as the formation of an oxide film on sidewalls of poly-silicon gate electrodes of transistors, and the formation of a silicon oxide film on the surface of a silicon substrate having different crystal plane directions according to portions due to prominences and depressions, e.g., the formation of a silicon oxide film serving as a gate insulating film in a manufacturing process of a three-dimensional transistor of a fin structure or a recess gate structure. Further, the present invention may be applied to the formation of a tunnel oxide film of a flash memory.

Although the method of forming a silicon oxide film as an insulating film is described in the above embodiment, the silicon oxide film formed by the method of the present invention may be converted into a silicon oxynitride (SiON) film through a nitrification process. In this case, although no particular limitation is imposed on a nitrification method, it is preferable to perform a plasma nitrification process by using a gas mixture containing Ar gas and N₂ gas. Further, the present invention may be applied to the formation of an oxynitride film by plasma oxynitriding using a gas mixture including Ar gas, N₂ gas, and O₂ gas.

Further, although a silicon substrate, which is a semiconductor substrate, is used as an object to be processed in the above embodiment, other semiconductor substrates, such as a compound semiconductor substrate, or substrates for FPDs, such as an LCD substrate, an organic EL substrate or the like, may be used.

### INDUSTRIAL APPLICABILITY

The present invention is preferably applied to the formation of a silicon oxide film in the manufacture of various semiconductor devices.

1. A plasma oxidizing method comprising:
placing an object to be processed, having a surface containing silicon and an uneven pattern with prominences and depressions, in a processing chamber of a plasma processing apparatus;
forming a plasma in the processing chamber under the condition that a proportion of oxygen in a processing gas ranges from 5 to 20% and a process pressure ranges from 267 Pa to 400 Pa; and
forming a silicon oxide film by oxidizing the silicon of the surface of the object by using the plasma,
wherein the silicon oxide film is formed such that a ratio (t_{c}/tₛ) of a film thickness t_{c} of the silicon oxide film formed at corners of upper ends of prominences of the uneven pattern to a film thickness tₛ of the silicon oxide film formed at side surfaces of the prominences ranges from 0.8 to 1.5, and
wherein a process temperature ranges from 200 to 800° C.

2. The plasma oxidizing method of claim 1, wherein the plasma is a microwave-excited plasma formed by exciting the processing gas by using a microwave introduced into the processing chamber by a planar antenna having plural slots.

3. The plasma oxidizing method of claim 1, wherein the uneven pattern formed on the surface of the object includes sparse and dense portions having sparse and dense prominences and depressions.

4. (canceled)

5. The plasma oxidizing method of claim 1, wherein the silicon oxide film is formed such that a ratio of a film thickness of the silicon oxide film formed at bottoms of the depressions of the uneven pattern at dense portions to a film thickness of the silicon oxide film formed at bottoms of the depressions of the uneven pattern at sparse portions is 85% or more.

6. The plasma oxidizing method of claim 1, wherein the proportion of oxygen in the processing gas ranges from 10 to 18%.

7. The plasma oxidizing method of claim 1, wherein the process pressure ranges from 300 Pa to 350 Pa.

8. The plasma oxidizing method of claim 1, wherein the processing gas includes hydrogen in a proportion of 0.1 to 10%.

9. (canceled)

10. A plasma oxidizing method comprising:
placing an object to be processed, having a surface containing silicon, in a processing chamber of a plasma processing apparatus;
forming a plasma of a processing gas including rare gas and oxygen in the processing chamber by radiating a microwave from a planar antenna having plural slots into the processing chamber; and
forming a silicon oxide film by oxidizing the silicon of the surface of the object by using the plasma,
wherein the plasma is formed under the condition the processing gas including oxygen of 5 to 20% is supplied into the processing chamber at a flow rate of 0.128 mL/min or more per unit volume (1 mL) of a plasma processing space, in which a plasma process is effectively carried out in the processing chamber, and a process pressure ranges from 267 Pa to 400 Pa, and the silicon oxide film is formed by oxidizing the silicon of the surface of the object by using the plasma.
wherein the silicon oxide film is formed such that a ratio (t_{c}/tₛ) of a film thickness t_{c} of the silicon oxide film formed at corners of upper ends of prominences of the uneven pattern to a film thickness tₛ of the silicon oxide film formed at side surfaces of the prominences ranges from 0.8 to 1.5, and
wherein a process temperature ranges from 200 to 800° C.

11. The plasma oxidizing method of claim 10, wherein the processing gas including oxygen of 5 to 20% is supplied into the processing chamber at a flow rate of 2,000 mL/min or more, when the volume of the plasma processing space, in which the plasma process is effectively carried out in the processing chamber, ranges from 15 to 16 L.

12. The plasma oxidizing method of claim 10, wherein an oxidation of the silicon using the plasma is performed while the object is heated, and the object is preheated for 5 to 30 seconds prior to the oxidation of the silicon.

13. The plasma oxidizing method of claim 10, wherein the processing gas further includes a hydrogen gas.

14. (canceled)

15. The plasma oxidizing method of claim 10, wherein the uneven pattern formed on the surface of the object includes sparse and dense portions having sparse and dense prominences and depressions.

16. (canceled)

17. The plasma oxidizing method of claim 15, wherein the silicon oxide film is formed such that a ratio of a film thickness of the silicon oxide film formed at bottoms of the depressions of the uneven pattern at dense portions to a film thickness of the silicon oxide film formed at bottoms of the depressions of the uneven pattern at sparse portions is 85% or more.

18. The plasma oxidizing method of claim 10, wherein the proportion of oxygen in the processing gas ranges from 10 to 18%.

19. The plasma oxidizing method of claim 10, wherein the process pressure ranges from 300 Pa to 350 Pa.

20. The plasma oxidizing method of claim 10, wherein the processing gas includes hydrogen in a proportion of 0.1 to 10%.

21. (canceled)

22. A plasma processing apparatus comprising:
a processing chamber which accommodates an object to be processed, having a surface containing silicon and an uneven pattern with prominences and depressions;
a processing gas supply unit which supplies a processing gas including rare gas and oxygen into the processing chamber;
a gas exhaust unit which evacuates the processing chamber to form a vacuum in the processing chamber;
a plasma generating unit which generates a plasma of the processing gas in the processing chamber; and
a control unit which controls the units to form the plasma in the processing chamber in which the object is placed under the condition that a proportion of oxygen in the processing gas ranges from 5 to 20% and a process pressure ranges from 267 Pa to 400 Pa, and to form a silicon oxide film by oxidizing the silicon in the surface of the object by using the plasma,
wherein the silicon oxide film is formed such that a ratio (t_{c}/tₛ) of a film thickness t_{c} of the silicon oxide film formed at corners of upper ends of prominences of the uneven pattern to a film thickness tₛ of the silicon oxide film formed at side surfaces of the prominences ranges from 0.8 to 1.5, and
wherein a process temperature ranges from 200 to 800° C.

23. (canceled)
